(19) United States
(12) Patent Application Publication
(10) Pub. No.: US 2013/0214870 A1
(43) Pub. Date: Aug. 22, 2013

(54) Robust Injection-Locked Local Oscillator

(71) Applicants: IMEC, (US); Vrije Universiteit Brussel, (US)

(72) Inventor: Giovanni Mangraviti, Leuven (BE)

(73) Assignees: Vrije Universiteit Brussel, Brussel (BE); IMEC, Leuven (BE)

(21) Appl. No.: 13/768,832

(22) Filed: Feb. 15, 2013

(30) Foreign Application Priority Data
Feb. 17, 2012 (EP) 12156057.7

(51) Int. Cl. H03B 5/08

(52) U.S. Cl. CPC H03B 5/08
USPC 331/117 R

(57) ABSTRACT

The present disclosure relates to an injection-locked local oscillator and a method for calibrating the same. The local oscillator includes an active circuit having at least one first resonator connected to the output of the active circuit, and at least one second resonator coupled to the at least one first resonator, thereby forming at least one coupled resonator. In another aspect, the present disclosure relates to a method for calibrating a local oscillator, the calibration being a two-step calibration based mainly on power measurement.

### CROSS-REFERENCE TO RELATED APPLICATION

This application claims priority to European Patent Application No. 12156057.7 filed on Feb. 17, 2012, the contents of which are hereby incorporated by reference.

### TECHNICAL FIELD

The present disclosure relates to local oscillators and, more specifically, to injection-locked local oscillators.

### DESCRIPTION OF THE RELATED TECHNOLOGY

The demand for realization of a single-chip transceiver for mm-wave applications (e.g. high data rate wireless 60 GHz communication, radar-based sensing at 77 GHz, and 94 GHz imaging) having low cost, low area footprint, and low power consumption is constantly increasing. For wireless transceivers, the local oscillator (LO) system is one of the transceiver's power critical blocks.

Currently, mm-wave LO systems are generally based on phase-locked loop (PLL) architectures that operate directly at mm-wave frequencies. In many integrated radios there is a long distance between the PLL and the mixers that are used for upconversion or downconversion. This is especially true in phased-array radios with beamforming implemented in the LO path or at baseband. Consequently, the PLL mm-wave output needs to be heavily buffered to the mixers. Such a mm-wave buffering is generally critical because of power consumption and sensitivity to parasitic capacitance and/or inductance. Further, mm-wave PLLs require mm-wave dividers, which are even more critical than mm-wave buffering. Alternative LO architectures using a low-frequency PLL for injection-locking of the oscillator to one of its harmonics have been proposed.

Injection locking of an oscillator is particularly appealing for mm-wave phased-array-antenna transceivers (FIG. 1). This is valid especially for transceivers with phase shifting at baseband or in the LO path, which require at least a mm-wave oscillator for each antenna. In this way, the mm-wave oscillators can be positioned close to the mixers while the LO signal that has to be distributed to the different antenna paths is an n-times lower-frequency injection-locking signal instead of a mm-wave LO signal. This leads to lower power consumption and a more robust LO distribution. In addition, injection-locking techniques can achieve comparable or even better phase-noise (PN) performance compared to mm-wave phase-locked loops.

However, the state-of-art injection-locked local oscillator (ILO) architectures for mm-wave CMOS transceivers have generally the disadvantage of being sensitive to disturbances (e.g. random phase changes in the injected signal) and temperature drifts, which bring the oscillator easily out of lock and thus decreasing their robustness. The proposed architectures can be split (mainly) into three groups: (1) ILOs with a narrow locking range, (2) ILOs with a wide tuning range, and (3) ILOs with a wide locking range but low quality factor (Q).

The first group of mm-wave injection-locked oscillators offers a narrow locking range (typically, much less than 1 GHz). These architectures, however, require either complex control loops or high-resolution frequency tuning to accurately calibrate the n-th harmonic of the injected frequency to fall within the locking range of the oscillator. Further, due to the narrow locking range, the LO could easily go out of lock in the presence of disturbances and temperature drifts, which decreases significantly the robustness of the oscillator.

The second group proposes ILO architectures that offer a wide tuning range, by tuning the locking range within a wide range of frequencies. Again, these architectures are characterized by a narrow locking range and require complex calibration circuitry for tuning the centre frequency around which the LO can be injection-locked, and thus suffer from poor robustness.

To improve the robustness of the LO, the third group proposes LO architectures with sufficiently wide locking ranges that also relaxe the requirements on calibration. However, existing solutions require injection of high-power signals into the oscillator and/or heavily lowered quality factor of the oscillator resonance tank. This results in either large power consumption or a low output signal level, which requires additional amplifying circuitry that inevitably increases the power consumption and area.

Musa et al, “A low phase noise quadrature injection locked frequency synthesizer for mm-wave applications,” IEEE JSSC, vol. 46, no. 11, pp. 2635-2649, November 2011, proposes a 60 GHz injection locked oscillator with a single resonance tank and a dual injection technique for improving the robustness of the local oscillator. Despite the dual-injection technique, this solution still offers a narrow locking range, i.e., 480 MHz at 60 GHz, and thus still requiring a complex frequency-measurement-based calibration.

Chan et al, “A 56-65 GHz injection-locked frequency tripler with quadrature outputs in 90-nm CMOS,” IEEE JSSC, pp. 2739-2746, December 2008, proposes an injection-locked LO architecture with single resonance tank. A wide locking range (56.5-64.5 GHz) is achieved by significantly lowering the quality factor of the resonance tank with a resistive loading, which leads to low amplitude of the output signal.

It is apparent from the above, that there is a need for robust local oscillator architectures with simplified calibration applicable for low power mm-wave application.

### SUMMARY

The present disclosure is generally directed to a robust local oscillator applicable for low power applications and, more specifically, to a robust injection-locked local oscillator with a resonance tank characterised by a wide locking range and a sufficiently high quality factor.

In one aspect the present disclosure, a local oscillator has a frequency range within which the local oscillator is locked and includes an active circuit. The active circuit has an input for receiving an input frequency tone for locking the local oscillator to an oscillation frequency. The active circuit also has an output for outputting an output frequency tone. The output frequency tone having a frequency that is equal to or higher that a frequency of the input frequency tone. The output frequency tone also having a frequency equal to the oscillation frequency. Further, the local oscillator includes at least one first resonator connected to the output of the active circuit and arranged for receiving the input frequency tone. The local oscillator also includes at least one second resonator coupled to the at least one first resonator to form at least one coupled resonator. The at least one coupled resonator is arrange to resonate at the oscillation frequency.

In one embodiment, the at least one coupled resonator is coupled magnetically. Alternatively, it can be also coupled capacitively.

In another embodiment, at least one of the first resonator or the second resonator is an LC resonator.

In yet another embodiment, the LC resonator includes a variable capacitor for adjusting the oscillation frequency of the local oscillator.

The proposed local oscillator is generally characterized by (i) a wide frequency range within which the local oscillator can be locked and (ii) a sufficiently high quality factor. The wide locking range is achieved by designing the local oscillator to comprise at least one coupled resonator with an equivalent impedance phase characterized by a wide flat region positioned around zero degrees. Advantageously, the power of the output frequency tone of the proposed local oscillator does not suffer from high penalty.

In another embodiment, the frequency range within which the local oscillator can be locked is at least in part set by adjusting a coupling factor of the at least one coupled resonator.

In a further embodiment, the locking frequency range is further adjusted by setting at least one parameter of the at least one coupled resonator.

In another embodiment, the at least one coupled resonator has an equivalent impedance phase with a flat region.

In yet another embodiment, the active circuitry of the local oscillator is differential.

As the person skilled in the art will readily recognize, the proposed local oscillator can be embedded in other oscillator implementations, for example, in differential and/or in quadrature injection-locked local oscillators.

Another aspect the present disclosure relates to a method for calibrating a local oscillator. In one example, the method includes selecting a frequency range within which the local oscillator is to be locked by adjusting at least one parameter of at least one first resonator, thereby shifting the center of the frequency range from one frequency to another frequency. An equivalent impedance phase of at least one coupled resonator is characterized with a flat region within the frequency region. The method also includes maximizing the frequency range, by adjusting at least one parameter of at least one second resonator, thereby positioning the flat region of the equivalent impedance phase at zero degrees. The width of the frequency region is at least in part defined by the coupling factor of the at least one coupled resonator.

In one embodiment, the locking frequency range is selected by adjusting the capacitance of the at least one first resonator.

In another embodiment, the locking frequency range is maximized by adjusting the capacitance of the at least one second resonator.

Indeed, by selecting a coupling factor such that the equivalent impedance phase of the coupled resonator is characterized with a flat region, and by further tuning some of the parameters defining the equivalent resonant frequency of the local oscillator resonator, the resonator can be tuned to provide a wide locking frequency range.

In one embodiment, maximizing of the width of the frequency range is based on measuring the output power of the local oscillator oscillation frequency.

Generally, the equivalent impedance magnitude of the local oscillator resonator is characterized by a relative minimum, which allows the second step of the calibration to be performed by measuring the power output frequency tone.

### BRIEF DESCRIPTION OF THE DRAWINGS

Various embodiments are described below in conjunction with the appended figures and figures description.

FIG. 1 illustrates an injection-locked local oscillator with a single resonator tank.

FIG. 2 illustrates a block scheme of an injection-locked local oscillator according to an embodiment of the present disclosure.

FIG. 3 illustrates an injection-locked local oscillator schematic according to one embodiment of the present disclosure.

FIG. 4 illustrates an injection-locked local oscillator schematic according to another embodiment of the present disclosure.

FIG. 5 illustrates the equivalent impedance phase and magnitude observed at the primary circuit of a coupled resonance tank for different values of the coupling factor K.

FIG. 6 illustrates the impedance phase of the coupled resonator of the present disclosure in comparison to the state-of-the-art approaches.

FIG. 7 illustrates the impedance magnitude of the coupled resonator of the present disclosure in comparison to the state-of-the-art approaches.

FIG. 8 illustrates the impedance phase and magnitude of the proposed coupled resonator for different C₂/C₁ ratios.

FIG. 9 illustrates the coarse tuning (first step of the calibration) of the proposed coupled resonator.

FIG. 10 illustrates the fine tuning (second step of the calibration) of the coupled resonator.

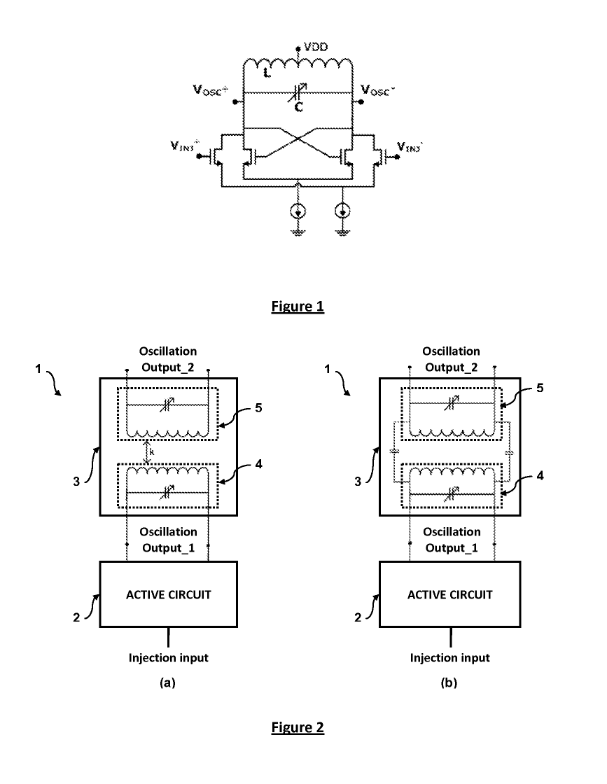

### DETAILED DESCRIPTION

The present disclosure will be described with respect to particular embodiments and with reference to certain drawings but the disclosure is not limited thereto. The drawings described are only schematic and are non-limiting. In the drawings, the size of some of the elements may be exaggerated and not drawn to scale for illustrative purposes. The dimensions and the relative dimensions do not necessarily correspond to actual reductions to practice of the disclosure.

Furthermore, the terms first, second, third, and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Moreover, the terms top, bottom, over, under, and the like in the description and the claims are used for descriptive purposes and not necessarily for describing relative positions. The terms so used are interchangeable under appropriate circumstances and the embodiments of the disclosure described herein can operate in other orientations than described or illustrated herein.

The term “comprising”, used in this application, should not be interpreted as being restricted to the means listed thereafter; it does not exclude other elements or steps. Rather, this term should be interpreted as specifying the presence of the stated features, integers, steps, or components as referred to, but does not preclude the presence or addition of one or more other features, integers, steps, components, or groups thereof. Thus, the scope of the expression “a device comprising means A and B” should not be limited to devices consisting of only components A and B. It means that with respect to the present disclosure, the relevant components of the device are A and B.

For wireless communication at data rates above 1 Gbit/s a frequency band of 7 GHz is allocated around 60 GHz. In this frequency band several applications are targeted with mass-market potential. Wireless consumer products require cheap implementation technologies in combination with low power consumption. For example, a downscaled digital CMOS, which is cheap for large-volume products, is capable of handling 60 GHz signals with baseband bandwidths around 1 GHz.

The robustness of local oscillator (LO) systems based on injection locking is improved by increasing their locking range. The robustness defines the sensitivity of the local oscillator to disturbances (e.g. random phase changes in the injected signal) and temperature drifts, which cause the oscillator to easily go out of lock. In other words, the more robust the oscillator, the less sensitive it is to disturbances. Further, improved local oscillator robustness lessens the constraints on the oscillator's calibration so that no complex tuning is needed before the operation of the LO system.

However, designing a LO resonant tank with a wide locking range represents a design challenge. An injection-locked LO is one of the main applications of injection locking in the field of RF IC design. An injection-locking scheme implies that the oscillator is locked to the n-th harmonic of the injected signal (e.g., n≧1). For n>1, the n-th harmonic of the injected signal is usually generated thanks to the non-linear behaviour of MOS transistors in the active core of the oscillator. Since such n-th harmonics are usually low in power, the injection-locking condition stays valid only over a narrow frequency range, which means that the locking range is narrow. The injection-locking condition is as follows:

$${I}_{INJ} \geq \frac{4}{π} I sin α \qquad ( 1 )$$

In Equation 1, I_{INJ} is the current injected in the oscillator, 4I/π is the first harmonic of the oscillation current when the oscillator is free-running, and α is the phase of the impedance of the resonant tank.

The locking range of an injection-locked oscillator can be defined as the frequency range over which the locking condition (Equation 1) remains valid. From a design point of view, Equation 1 shows that the injection-locking range can be improved by (1) injecting signals with a sufficient amount of power (e.g., I_{INJ} with a high amplitude) and/or (2) designing a resonance tank with small impedance phase (e.g., α is close to zero degrees over a wide frequency range).

The first condition requires a power consumption that is unacceptable for low-power applications, while the second condition is generally implemented by designing the resonance tank with a low quality factor (Q). Lowering the quality factor, implies a wide locking range but also a weak output voltage of the injection-locked oscillator, thus requiring more power for output buffering. Hence, designing an injection-locked oscillator with wide locking range and relatively high quality factor is a design challenge.

In one embodiment, the present disclosure describes an injection-locked local oscillator (1) with an active circuit (2) and a coupled resonator (3), characterized by an impedance phase plateau around zero degrees and a relatively high quality factor (FIG. 2). A coupled resonator with a wide locking range may be designed with different types of resonator tanks (e.g. LC tanks) which may be coupled in different manners, e.g., magnetically or electrically (capacitively) coupled as shown in FIG. 2(a) and FIG. 2(b), respectively. For simplicity the coupled resonator is shown as two LC resonators, however, each resonator at the primary circuit (4) and/or at the secondary circuit (5) may consist of multiple of resonators.

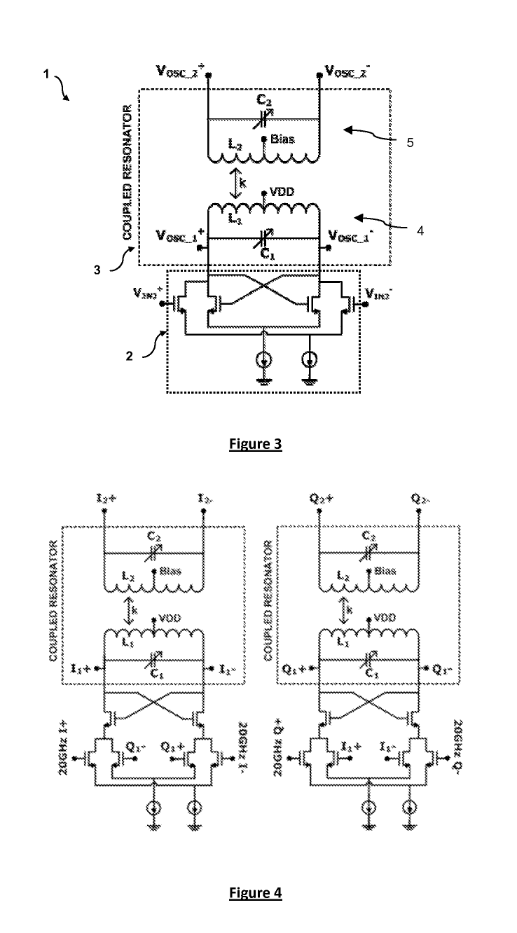

FIG. 3 shows an example of a possible injection-locked LO architecture (1), that includes an active circuit (2) and a coupled resonator (3). The active circuit consists of a first pair of NMOS transistors through which an external signal (V_{INJ}) is injected into the oscillator and a second pair of cross-coupled NMOS transistors. In this architecture, the coupled resonator (3) includes two magnetically-coupled LC tanks forming a transformer, wherein the first resonator tank (4) connected to the active circuit (2) is formed by L₁ and C₁, and the second resonator (5) by L₂ and C₂. For this example architecture, C₁ and C₂ are variable capacitors and can be used for calibration of the free-running frequency of the coupled resonator (3), as will be explained below. As mentioned above, different type of resonators coupled using different schemes are also possible. The output of the local oscillator can be taken at the primary circuit (such as at nodes V_{OSC}_{_{—}}₁+ and V_{OSC}_{_{—}}₁−) or at the secondary circuit (such as at nodes V_{OSC}_{_{—}}₂+ and V_{OSC}_{_{—}}₂−) of the coupled resonator.

Although, FIG. 3 shows a differential injection-locked oscillator, the skilled person in the art will immediately recognize that the same topology can be generalized for single-ended oscillators.

Further, the skilled person will also recognize that the proposed injection-locked LO architecture can also be used in various injection-locked architectures, for example, sub-harmonic injection-locked quadrature voltage-controlled oscillator (SHIL-QVCO) architectures as shown in FIG. 4, where a 20 GHz quadrature signal is injected to lock the SHIL-QVCO at 60 GHz oscillation frequency. More specifically, this SHIL-QVCO consists of two coupled voltage-controlled oscillators (VCO). Similarly to the architecture of FIG. 3, each of these two VCOs consists of an active circuit and a coupled resonator. The active circuit includes a first pair of NMOS transistors through which an external 20 GHz quadrature signal (20 GHz I+, 20 GHz I− and 20 GHz Q+, 20 GHz Q− in FIG. 4) is injected into the oscillator, a second pair of NMOS transistors through which the two VCOs are coupled to each other (I₁+, I₁− and Q₁+, Q₁−), and a third pair of cross-coupled NMOS transistors. The same coupled resonator as in FIG. 3, comprising two magnetically-coupled LC tanks forming a transformer is used, wherein the first resonator tank connected to the active circuit is formed by L₁ and C₁, and the second resonator by L₂ and C₂. In particular, C₁ and C₂ are variable capacitors and can be used for calibration of the equivalent impedance phase of the coupled resonator, as explained further below. The output of this SHIL-QVCO can be taken at the primary circuit of the coupled resonators (such as at nodes I₁+, I₁−, Q₁+, Q₁− in FIG. 4) or at the secondary (such as at nodes I₂+, I₂−, Q₂+, Q₂− in FIG. 4).

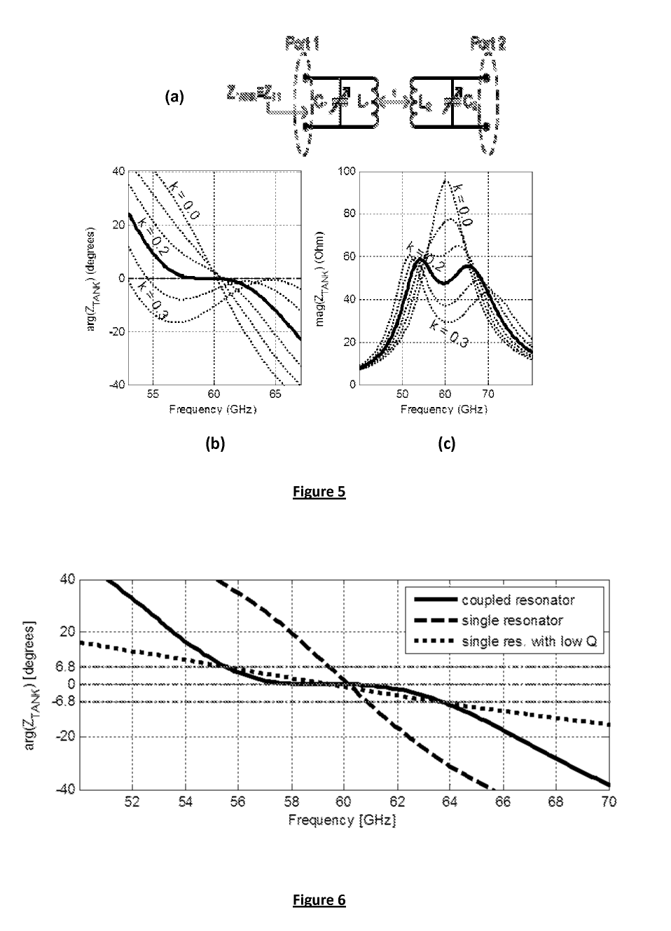

The properties of a coupled resonator tank are explained by way of example. FIG. 5 shows the magnitude and phase of the impedance of a coupled resonator with respect to different values of coupling factor (k). More specifically, this impedance is the equivalent impedance seen at the primary of the coupled resonance tank (e.g., Z₁₁). In other words, if we consider the coupled resonator as a two-port network, as shown in FIG. 5(a), with Port 1 at the primary circuit and Port 2 at the secondary circuit, the impedance here discussed would be the so-called Z₁₁. FIG. 5(b), shows that a coupling factor of k=0.2 provides a phase plateau of approximately 5 GHz covering most of the complete 60 GHz communication band. As can be seen in FIG. 5(c), some penalty with respect to the impedance magnitude is observed if compared to a single-resonator tank (i.e. k=0.0). More specifically, the coupled resonator with a coupling factor of k=0.2 has about 2 times lower impedance magnitude than the single resonator (k=0.0). This penalty implies a lower voltage oscillation amplitude in the oscillator. However, as it will become apparent below, this penalty is significantly lower in comparison to a single resonator with low Q factor.

A comparison to the state-of-art approaches can be performed by observing the phase and the magnitude of the resonance tank impedance (the phase and magnitude of Z₁₁). Generally speaking, the impedance phase influences the locking range (see Equation 1) while the impedance magnitude influences the magnitude of the output voltage oscillation (e.g., the higher impedance magnitude, the higher voltage oscillation magnitude). FIG. 6 and FIG. 7 depict a comparison between the above-mentioned state-of-art approaches and the approach proposed in the present disclosure, e.g.,
i) an injection-locked oscillator with a single resonator;
ii) an injection-locked oscillator with a single resonator with low Q factor;
iii) an injection-locked oscillator with a coupled-resonator, as proposed in the present disclosure.
   For a fair comparison the single-resonance tank has been modelled with the same Q factor as the coupled-resonance tank, while the single-resonance tank with lowered Q factor (e.g., a single resonator with a resistive loading) has been modelled to have the same locking range of the proposed coupled resonator. In particular, FIG. 6 shows the impedance phase of the resonance tank, e.g., arg(Z₁₁) arg(Z_{TANK}), and FIG. 7 shows its impedance magnitude, e.g., mag(Z₁₁) mag(Z_{TANK}).

Because injection locking occurs within a frequency range where the impedance phase of the LO is close to zero degrees (between −6.8° and +6.8° in FIG. 6), a conventional oscillator with a single-resonance tank must be calibrated such that its free-running oscillation frequency falls very close to the injected frequency (within 59-61 GHz in FIG. 6). In other words, this system exhibits a narrow locking range. Such calibration is complex and it requires a fine frequency sensing.

In contrast, oscillators with a single-resonance tank with low Q factor are characterized by a wide locking range. Hence, no complex calibration is required as the locking range of the free-running oscillation is wide (locking range of 56-64 GHz in FIG. 6). However, as explained above, these oscillators have a heavy penalty in output power (e.g., the magnitude of the output voltage oscillation is lowered). FIG. 7 shows that their impedance magnitude (mag(Z_{TANK})≈20Ω) is about 4 times lower than a conventional oscillator with a narrow locking range (mag(Z_{TANK})≈95Ω).

The proposed oscillator with a coupled-resonance tank does not require a complex calibration, thanks to its wide locking range (56-64 GHz as shown in FIG. 6). Compared to a conventional approach with a single-resonance tank and low Q, the proposed LO offers about two times higher output power (mag(Z_{TANK})≈55Ω).

Depending on the type of coupled resonator, some calibration is still needed to set the resonance tank impedance phase plateau around zero degrees. For the proposed coupled resonator of FIG. 2, the calibration requires that the self-resonance frequencies of the first resonator (2) and the second resonator (3), defined as ω₁ and ω₂ respectivel, are tuned such that Equation (2) is satisfied.

$$\frac{{ω}_{2}}{{ω}_{1}} \approx \sqrt{( 1 - {k}^{2} )} \qquad ( 2 )$$

In another embodiment, the present disclosure proposes a method for calibrating the proposed injection-locked oscillator with a coupled resonator. A two-step calibration is proposed, assuming that the self-resonance frequency of each of the two resonators can be tuned. Firstly, a coarse calibration (or a low-resolution tuning) of the self-resonance frequency of the first resonator (ω₁) is performed in order to select an operating frequency band for the oscillator. Frequency sensing may be required but, since this step requires only a coarse tuning, such sensing is much simpler in comparison to the fine frequency sensing required for tuning narrow-locking-range oscillators. Once ω₁ is fixed, a fine calibration (or a high-resolution tuning) of the self-resonance frequency of the second resonator (ω₂) is performed in order to set the phase plateau of Z_{TANK} around zero degrees. More specifically, ω₂ must be set so that Equation 2 is fulfilled. This tuning of ω₂ requires only the monitoring (measuring) of the output power of the oscillator, in other words, detecting the relative minimum of the impedance magnitude.

Considering the coupled resonator shown in FIG. 3, Equation (2) can be written as follows:

C₁/C₂≈L₂/L₁·(1−k²) (3)

One way to adjust the self-resonance frequency of this coupled resonators is by, for example, adjusting the variable capacitors C₁ and C₂ until the ratio C₂/C₁ satisfies Equation 3.

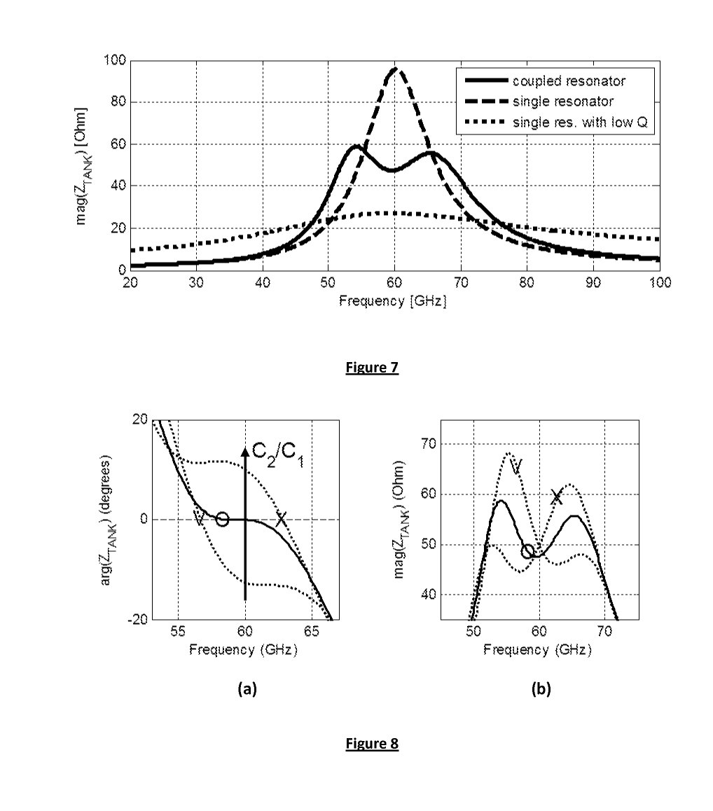

FIG. 8 illustrates details of the calibration for the coupled resonator shown in FIG. 3, wherein FIG. 8(a) shows the effect of changing the ratio C₂/C₁ with respect to the position of the impedance phase plateau, while FIG. 8(b) shows the corresponding impedance magnitude that defines the output power of the (voltage) oscillation signal. Adjusting the variable capacitors C₁ and C₂ reflects a shift in the phase plateau of the free-running oscillation (Z_{TANK}) along the y-axis. Three examples for phase plateau positioned (a) above zero degrees, (b) at zero degrees and (c) below zero degrees are illustrated by the points ‘V’, ‘O’, and ‘X’ respectively. For the setting corresponding to Point ‘V’, the locking range is narrow as the impedance phase curve around zero degrees has a steep slope (see FIG. 8(a)), and the output power of the oscillation signal is high, corresponding to the output power of a single resonator (e.g., mag(Z_{TANK})≈65Ω in FIG. 8(b)). Similar observation can be made for the setting corresponding to Point ‘X’. Point ‘O’, however, shows that when the phase plateau positioned at zero degrees, the free-running oscillation phase has a relative minimum (as mag(Z_{TANK}) has a relative minimum) This relative minimum, which is observed in the impedance magnitude, is marked by Point ‘O’ in FIG. 8(b). In other words, by modifying the C₂/C₁ ratio (or ω₂/ω₁ ratio), the free-running oscillation amplitude encounters a relative minimum as the phase plateau reaches zero degrees. This allows the system to be calibrated by detecting the relative minimum of the oscillation amplitude. Such a calibration is thus based on power measurement and not on a frequency measurement, while oscillators with a narrow-locking range do require a high-resolution RF-frequency measurement.

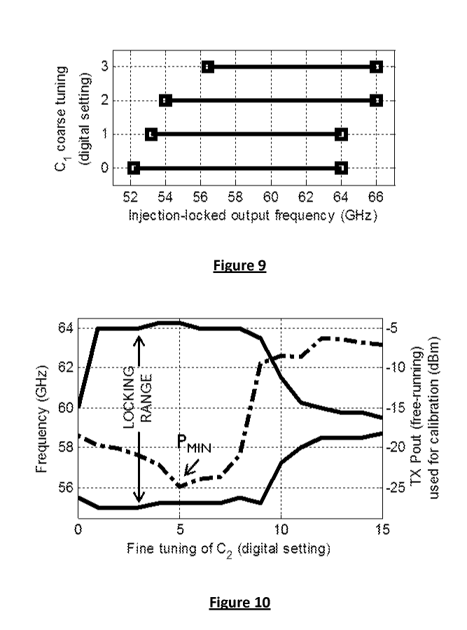

FIGS. 9 and 10 illustrate more details of the two-step calibration approach for the example architecture of mm-wave SHIL-QVCO shown in FIG. 4. In particular, FIGS. 9 and 10 show some measurements performed on an implementation in a 40 nm CMOS technology. Firstly, a coarse calibration is performed for selecting an operating frequency band for the oscillator by coarsely tuning the value of capacitor C₁, as shown in FIG. 9. For the course calibration, only a 2-bit resolution for the capacitor C₁ is sufficient for tuning the locking range over a wide band, e.g., 52-66 GHz. In the figure, four different operating frequency bands are shown, e.g., 52-64 GHz, 53-64 GHz, 54-66 GHz, and 56.5-66 GHz. Once the value of C₁ is defined, a fine calibration is performed for setting the phase plateau of the impedance of the resonant tank at zero degrees by tuning capacitor C₂. FIG. 10 shows the effect of the fine tuning C₂ on the measured oscillation power (shown as dashed-dotted line) and the corresponding locking range (shown as a distance between the solid lines). The fine calibration is performed when the oscillator is free-running, such as when no signal is injected. Under this a condition, the relative minimum in power can be easily detected. A relative minimum in the oscillation power (indicated by P_{MIN} in FIG. 10) is detected when C₂ is set to 5. This also corresponds to a maximum locking range, i.e. a locking range of more than 8 GHz.

In summary, the proposed injection-locked local oscillator with a coupled resonator offers a wide locking range with a relatively high quality factor. The proposed architecture is suitable for low-power applications as first, it does not require powerful signal injection, and second, it does not require power-expensive amplification circuit for output buffering. Furthermore, the architecture allows for simple calibration mainly based on RF power measurement, which is significantly simpler than an accurate RF frequency measurement.

1. A local oscillator having a frequency range within which the local oscillator is locked, the local oscillator comprising:
an active circuit having an input for receiving an input frequency tone for locking the local oscillator to an oscillation frequency and an output for outputting an output frequency tone, wherein the output frequency tone has a frequency equal to or higher than the input frequency tone, and wherein the output frequency tone has a frequency equal to the oscillation frequency;
at least one first resonator connected to the output of the active circuit and arranged for receiving the input frequency tone; and
at least one second resonator coupled to the at least one first resonator to form at least one coupled resonator, wherein the at least one coupled resonator has an equivalent impedance phase with a flat region and is arranged to resonate at the oscillation frequency, the width of the flat region being at least in part defined by a coupling factor of the at least one coupled resonator.

2. The local oscillator as in claim 1, wherein the at least one coupled resonator is coupled magnetically.

3. The local oscillator as in claim 1, wherein the at least one coupled resonator is coupled capacitively.

4. The local oscillator as in claim 1, wherein at least one of the first resonator or the second resonator is an LC resonator.

5. The local oscillator as in claim 4, wherein the LC resonator includes a variable capacitor for adjusting the oscillation frequency.

6. The local oscillator as in claim 1, wherein the frequency range is at least in part set by adjusting the coupling factor of the at least one coupled resonator.

7. The local oscillator as in claim 1, wherein the frequency range is adjusted by setting at least one parameter of the at least one coupled resonator.

8. The local oscillator as in claim 1, wherein the active circuit is differential.

9. A method for calibrating a local oscillator as in claim 1, comprising:
selecting a frequency range within which the local oscillator is to be locked by adjusting at least one parameter of the at least one first resonator, thereby shifting a center of the frequency range from one frequency to another frequency, wherein the equivalent impedance phase of the at least one coupled resonator is characterized with a flat region within the frequency region and the width of the flat region being at least in part defined by the coupling factor of the at least one coupled resonator; and
maximizing the frequency range, by adjusting at least one parameter of the at least one second resonator, thereby positioning the flat region of the equivalent impedance phase at about zero degrees.

10. The method for calibrating as in claim 9, wherein the at least one parameter of the at least one first resonator is the capacitance.

11. The method for calibrating as in claim 9, wherein the at least one parameter of the at least one second resonator is the capacitance.

12. The method for calibrating as in claim 9, wherein the positioning of the flat region is based on measuring the output power of the oscillation frequency.
